(19) United States
(12) Patent Application Publication
(10) Pub. No.: US 2006/0169969 A1
(43) Pub. Date: Aug. 3, 2006

(54) Bandgap cascade cold cathode

(75) Inventors: Chia-Gee Wang, Milwood, NY (US); Adam Filios, Jersey City, NJ (US)

Correspondence Address: LADAS & PARRY, 26 WEST 61ST STREET, NEW YORK, NY, 10023, US

(73) Assignee: Nanodynamics 88

(21) Appl. No.: 11/345,143

(22) Filed: Feb. 1, 2006

Related U.S. Application Data
(60) Provisional application No. 60/649,216, filed on Feb. 2, 2005.

(51) Int. Cl. H01L 29/06

(52) U.S. Cl. 257/10; 313/310

(57) ABSTRACT

A bandgap cascade cold cathode is obtained by constructing a wide bandgap Si/C superlattice thin film; depositing Si on the epitaxial silicon surface under CVD or ALD; depositing on the Si/C surface a first metal effective to form a metal-silicide electrode; etching away the silicon substrate to form an effectively smooth Si/C surface thereon; coating the effectively smooth Si/C surface with a thicker second effective metal to form a Schottky electrode surface on which a layer of about 200 nm Pt or Au is coated with edges masked off and welded onto a Cu electrode disc as a heat sink. During avalanche multiplication under reverse bias over the Si/C layer, the bandgap energy cascades from the Schottky electrode to the sink electrode and is used to balance against the work function of the sink electrode, thereby allowing the sink electrode to function as a cold cathode emitter at a reduced applied external field.

### BACKGROUND OF THE INVENTION

The invention relates to bandgap cascade cold cathodes, their use and methods of making them.

Manipulating electrons in an evacuated enclosure for electron microscopes, X-ray tubes, traveling wave tubes, free electron lasers, etc. requires a bright, steady, and well defined e-beam source. Thermionic emissions, typically from a tungsten filament, could deliver up to 10 Amp/cm², but will incur a reduced life when the emission increases much beyond one A/cm². Cold cathodes, particularly of a planar structure, could theoretically deliver a much higher current density if the electron affinity or work function of the emitter could be greatly reduced. In this disclosure, we will make use of “hot electrons” generated by the cascade of a breakdown avalanche multiplication of a semiconductor material such as the hot electrons in a Schottky diode reaching the solid/vacuum interface, to effectively reduce the work function for enhanced surface emissions.

Schottky Diode Under Avalanche Multiplication As an Example

Among semiconductor device configurations, the simplest is the Schottky diode. It is composed of a slice of semiconductor with one smooth surface coated with a metal electrode serving as the Schottky surface and the other not so smooth surface also made conductive serving as the source or sink. Electrons can flow relatively freely with small resistance from the rough sink electrode to the smooth Schottky electrode. But when the Schottky electrode becomes negatively charged, the smooth uniform field drives the free electrons away from the surface electrode, forming a carrier void and therefore a depleted insulating region. The depletion thickness extends as the field increases, and could reach the sink electrode. More bias delivers a higher field over the material.

### SUMMARY OF THE INVENTION

Under an applied field, some electrons from the Fermi sea will always tunnel through the tilted band edge to form a leakage current. When the applied field is increased to a sufficient level so that carriers under the field are accelerated within a mean-free-path to gain sufficient energy so that the scattering would create an electron-hole (e-h) pair, and this nascent e-h pair in turn could also accelerate within a mean-free-path to gain sufficient energy to scatter and create subsequent e-h pairs, a cascade of avalanching multiplication is thus commenced. Depending on the e-h scattering and annihilation efficiencies, or the ionization efficiency of the semiconductor material, the multiplication factor of the avalanching carriers for each mean-free-path distance can be as low as one—no effective avalanche over the material, to as high as two—the carriers would double in number over each and every mean-free-path field length. This avalanche will terminate at the sink electrode whose in-situ equi-potential surface would provide no acceleration beyond. But for carriers reaching the sink electrode with kinetic energy of the bandgap, or fractions of the bandgap, their energy can readily be utilized to balance against the work function of the material for cold cathode emissions.

Thus, during avalanche multiplication under reverse bias over an Si/C layer, the bandgap energy cascades from the Schottky electrode to the sink electrode and is used to balance against the work function of the sink electrode, thereby allowing the sink electrode to function as a cold cathode emitter at a reduced applied external field.

Bandgap Energy Cascade

Avalanching carriers gaining sufficient energy in the semiconductor within one mean-free-path can scatter and create electron-hole pairs. The newly created carriers are the “hot carriers”, with each hot carrier having at least the bandgap energy in order to maintain the process of avalanche multiplication. These hot electrons cascading to the sink electrode become hot surface electrons. The kinetic energy of these electrons in a wide bandgap material is typically ˜3 eV, which can be used to balance against the work function of the material at ˜4.5 eV for cold cathode functions. Therefore, a construction of the Schottky cold cathode under bandgap cascade can be outlined as follows:
Schottky electrode is constructed on a smooth semiconductor layer serving as the Schottky diode.
The semiconductor layer should be sufficiently thin in order to allow a complete depletion and the avalanching carriers could readily reach the sink electrode with each pulse of applied field.
Depending on the ionization efficiency of the material structure, the multiplication factor at unity implies an infinite material thickness while a factor of two implies a thousand fold increase in carrier number density over every 10 mean-free-path lengths.
The sink electrode termination, such as a silicide electrode, would serve as the planar cathode emitter.

For example, a bandgap cascade cold cathode is obtained by treating surfaces of an effectively thin silicon wafer substrate with HF acid to remove the surface oxides and other impurities while leaving at least an epitaxial surface thereof with dangling hydrogen atoms; depositing on the epitaxial surface an effectively thin layer of Si either by SiH₄ under CVD (chemical vapor deposition) or silicon beam under ALD (atomic layer deposition) at 650° C. to obtain an epitaxial surface layer thereon for superlattice construction; constructing a few periods of Si/C at about one nm/period on the epitaxial surface layer to form an Si/C surface; depositing on the Si/C surface a first metal effective to form a metal-silicide electrode a few 10s of nm thick; etching away the silicon substrate to termination chemically when it reaches the Si/C superlattice boundary to form an effectively smooth Si/C surface thereon; coating the effectively smooth Si/C surface with an effectively thick second effective metal such as nickel to form a Schottky electrode surface on which a layer of about 200 nm Pt or Au is coated for chemical stability while masking off an edge of the Schottky surface from the metal coatings for edge-termination of the field as a leakage protection; welding the Pt or Au coating onto a Cu electrode disc having the same diameter as the Schottky electrode surface, the Cu electrode being sufficiently massive for a heat sink of thermal management; and placing a ring-shaped contact on the Si/C surface for delivering a positive pulse that initiates avalanche multiplication over the Si/C as a cathode emitter.

The applied field of the Schottky surface diode can be modulated at high frequencies, and for each pulse, a breakdown voltage is applied in order to commence an avalanche multiplication, to generate hot electrons cascading to the sink electrode. This sink electrode surface under the influence of a separate external field becomes the enhanced cathode emitter. While a Schottky diode is used for illustration, any p-n junction diode material could be applied with the same avalanche multiplication rationale under a breakdown bias.

### BRIEF DESCRIPTION OF THE DRAWING

Preferred embodiments will now be described with reference to an illustrative but not limitative drawing wherein:

FIG. 1 shows energy levels of a superlattice quantum well emitter at Schottky reverse bias Vᵣ and without avalanche or space charge;

FIG. 2 shows Schottky emitter with resonant tunneling with space charge and hot electrons having ≧3 eV to commence the avalanche by initiating electron-hole (e-h) pairs; and

FIG. 3 is an exploded bottom/front perspective view of a preferred embodiment of a bandgap cascade cold cathode and its use.

### DESCRIPTION OF PREFERRED EMBODIMENTS

Combining the Static and Dynamic Processes

Four recent static schemes of surface structuring and material selections described by the Fowler-Nordheim model can be summarized as seeking field emission with the lowest applied field. A dynamic model on the other hand, may be compared to the activities of a Faraday cup, where carriers would enter the cup, or as considered below travel to the vacuum, by passing through a gate potential barrier. This barrier usually consists of a chopper to be used for energy discrimination of the charged particles. All the static schemes of surface structuring and barrier lowering with space charges etc. can be considered as lowering the effective gate potential which increases the probability for the charged particles to passing through.

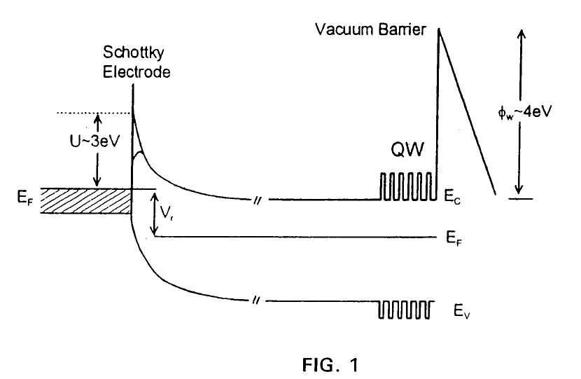

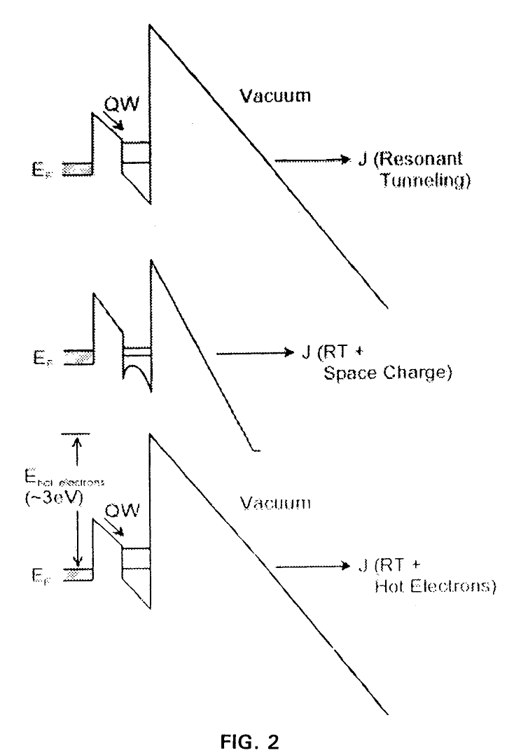

In our dynamic model, the kinetic energy of the electron cascade may be substantially more energetic than the gate potential or the work function of the material, therefore the emission will be limited mostly by the avalanching current and not by the detailed structures of the surface barrier as governed by the Fowler-Nordheim model. The static and dynamic energy profiles using Si/C superlattice are outlined in FIGS. 1 and 2.

Avalanche Cascade Under a Schottky Electrode

Schottky diodes are usually constructed with a heavily doped substrate with a nearly intrinsic epitaxial (epi)-layer coated with the Schottky electrode. The heavily doped substrate is necessary to reduce the material resistance to the forward current, while the near intrinsic epi-layer with low carrier concentration is necessary to sustain the reverse bias with a small leakage current. When the Schottky electrode is applied with a negative bias, the applied field pushes the electrons away from the electrode, causing a void of free carriers and thus a depletion region with high negative resistance. This negative bias from the Schottky electrode can be exerted equally well by a positive bias placed at the source electrode opposite to the Schottky electrode. As the bias increases, the depleted region extends, and as the depletion thickness reaches to the sink electrode, the entire Schottky layer becomes depleted.

Increasing the bias further, the level of the applied field over the dielectric becomes so high that the leakage carriers in the region become accelerated within a mean-free-path to scatter and create nascent electron-hole (e-h) pairs, which in turn, would initiate additional e-h pairs etc. and thus initiate the dynamics of avalanche cascade. The cascade current is limited by the number density of the e-h pairs as their polarized presence would neutralize the applied field in the dielectric material.

FIG. 1 is the band energy profile of a superlattice Si/C Schottky on silicon substrate without avalanche. FIG. 2 is the superlattice quantum well Schottky layer with the usual tunneling current to the vacuum, with space charges to effectively lower the work function, and with avalanching hot electrons to kinetically balance against the work function. Note that during the avalanching cascade, hot electrons of the order of 10²⁰/cm²-sec are accelerated by the applied field within a mean-free-path to reach the surface. Having such a dynamic event, those carriers without sufficient energy to leave become accumulated as space charges are not the main event. They are like snow falls in a mountain during a real avalanche and could only contribute as a perturbation relative to the avalanching cascade flow. Therefore in the band energy diagram with avalanching shown in FIG. 2, the contribution of space charges to the barrier lowering is not included.

Cascade Carriers with Bandgap Energy

For our cold cathode application, the material responsible for forward resistance is of no concern because there is no current flow from the vacuum to the electrode. We need to focus on the energetic avalanching electrons to balance against the work function, implying that the larger the bandgap to create the e-h pairs, the higher the hot electron energies and the more useful for them to fly across the work function barrier. This combination of high current density with large bandgap energy is rather unique in our requirement of the material characteristics. Designs of Zener diode, for example, call for mainly a precise breakdown voltage, which is not sufficient to satisfy the functions of the proposed bandgap cascade emitter. The bandgap, the dielectric constant, the breakdown voltage, and the thermal conductivity of several well known potential materials are listed in Table 1 below:

| | | | Breakdown | Thermal |
|---|---|---|---|---|
| | Dielectric | Bandgap | Field | Conductivity |
| | Constant | (eV) | (MV/cm) | (W/° C.-cm) |
| Si | 11.7 | 1.12 | 0.3 | 1.49 |
| GaAs | 13.1 | 1.42 | 0.4 | 0.46 |
| GaN | 9.0 | 3.49 | 3.3 | 1.7 |
| SiC | 9.7 | 3.0-3.2 | 3 | 3.5-5 |
| Ti0₂ | 86 | | | 0.1 |
| Si0₂ | 3.9 | 9.1 | 10 | 0.14 |

From Table 1 above, cold cathode with a very high emitter current may be obtained by using large bandgap for highly energetic hot electrons with material having high carrier concentration. Insulators such as SiO₂ have high bandgap but low carrier concentration, while silicon can have high carrier concentration but low bandgap value. We have some in-house expertise for Si/O and Si/C superlattice fabrications, and their bandgaps are 2.3-3.1 eV as measured by photo-luminescence. These bandgap values may be engineered to an even higher level by reducing the silicon fraction in the superlattice construction.

Outline of the Bandgap Cascade Cathode

Avalanching carriers gaining sufficient energy in the semiconductor within one mean-free-path to scatter and create e-h pairs, are the “hot carriers”, and when they arrive at the sink electrode, they can be the desired hot surface electrons. The kinetic energy of these electrons is typically ≧3 eV, which will be used to balance against the work function of the cold cathode emitter at about 4 eV, or effectively below 3 eV when certain potential lowering structures are incorporated. The applied field of the Schottky electrode can be modulated with high frequencies, and for each pulse, a breakdown voltage would be exerted to induce the avalanching cascade. This avalanche generates hot electrons all the way to the sink electrode. The sink electrode, under a separate applied field, becomes the enhanced cold cathode emitter. The desired characteristics of the Schottky bandgap cascade cold cathode are outlined as follows:
Schottky electrode is constructed on a semiconductor layer with a relatively large bandgap. The electrode should have a large potential difference, such as Nickel on silicon at 1.6 eV, in order to maintain stability under an elevated temperature.
The depletion layer should be sufficiently thin in order to minimize the thermal load from the avalanching drive.
The sink electrode, such as Zr-silicide termination serving as the planar cold cathode emitter, should have a low work function and be constructed ultra-thin and be made conductive using an electrode; of, for example, a metal net.
   Thermal Budget and Outline of Emitter Structure

For a Schottky diode, the forward current can typically be orders of magnitude higher than the limit of thernionic emissions under a few A/cm². The avalanching cascade driven by a reverse bias, or the breakdown current, is governed by the carrier concentration and the mobility of the material. Power dissipation during the avalanche, however, can be much higher than the forward current because of the high potential drop across the layer under the reverse bias. Consider for example, the silicon Schottky under a breakdown field of 0.4 MV/cm over a thickness of 25 μm. To drive the breakdown, it would require an applied voltage ˜1,000 Volts, and if an avalanching cascade of 10 A/cm² is maintained during the breakdown, the thermal load of the depletion layer can be 10 kW/cm², a thermal budget well beyond any semiconductor material to conduct and dissipate. The key here is therefore to reduce the semiconductor layer thickness from tens of μm to sub-μm, while allowing the cold cathode to be mounted on a massive electrode as heat sink.

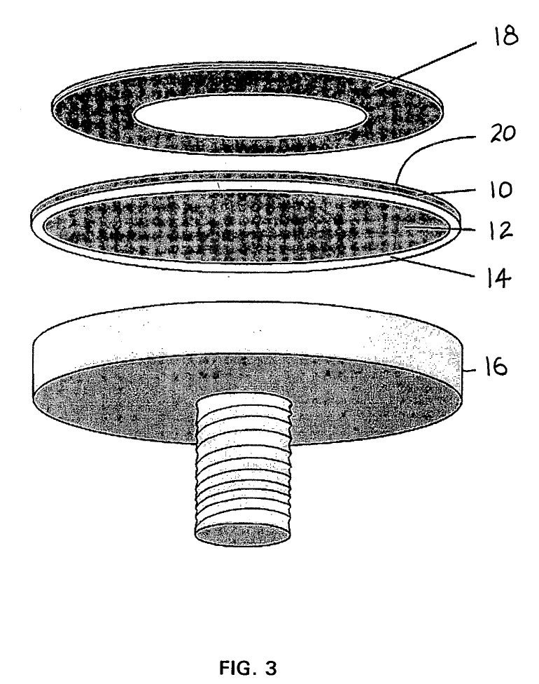

The disclosed depleted Schottky layer at sub-μm is really a thin and uniform device constructed epitaxially with two terminals; one for thermal management as well as for the delivery of electrons, and the other as emitter pulsed by a sufficiently high applied voltage to drive the bandgap cascade. To construct the thin, uniform and precise semiconductor layer, we will use a silicon-based superlattice Si/C with high bandgap (˜3 eV), high thermal conductivity (˜4 W/° C.-cm) and high dielectric constant (˜9). The construction steps are outlined as follows:
A thin near intrinsic silicon wafer with good epitaxy is surface treated with HF acid to remove the surface oxides and other impurities while covering the epi-surface with dangling hydrogen atoms.
A thin layer of silicon using silicon beam under ALD is deposited at 650° C. to obtain an epitaxial dimer surface of high quality.
Several hundred periods of Si/C, at one nm/period, are constructed on the epi-surface of the silicon wafer, with interface strain at under 1% because of the superlattice architecture.
On the Si/C surface, an ultra-thin metal such as Zr with relatively low work function, is deposited at an elevated temperature to form the Zr-silicide as the sink electrode emitter, plus a metal network on the Zr surface to provide electric conductance as well as allow the emitter surface some freedom to discharge.
The initial silicon substrate will be etched away with HCl. The etching process will terminate chemically when the acid reaches the Si/C superlattice.
The newly etched surface will be covered with a few atomic layers of silicon to form an epi-surface and cover the surface with a relatively thick Nickel layer to make use of the Si/Ni interface potential of 1.6 eV in order to obtain thermal stability for the Schottky electrode. Edge of the Nickel surface is masked off to make room for surface oxide for edge-termination as a leakage protection.
The Nickel surface is coated with Pt or Au for chemical stability and welded onto a copper electrode disc (FIG. 3) having the same diameter as the wafer-sized Schottky layer. The Cu-disc can be mounted onto a large electrode or heat sink for thermal management.
A contact will be placed on the metalized silicide cathode emitter to deliver the positive pulse necessary for the cascade. This layered device is very robust.
   Thermal Budget and Device Construction

For a Schottky diode, the forward current can typically be several hundred A/cm² as compared to thermionic emissions of at most a few A/cm². The avalanching current under a reverse bias, or the breakdown current is governed by the same scattering-limited carriers movements of the material. Power dissipation during the avalanche multiplication, however, can be much higher than the forward current because of the high reverse field. Consider for example, a silicon Schottky under a breakdown field of 3 Volt/mfp (mean-free-path in silicon is ˜3 nm), a thickness of 10 μm, during breakdown would require an applied voltage of up to 10,000 Volts. If an avalanching current of 100 A/cm² is obtained during the breakdown, the power density experienced by the layer can be 10⁶ Watt/cm², a thermal budget much too high for most semiconductor materials to dissipate. A pulsed emission, with a duty cycle under 0.1% may therefore be necessary. In addition, a reduction of the semiconductor layer thickness for a reduced bias would reduce the power as well as enhance the heat dissipation. The layer thickness can be reduced from tens of μm to under 0.1 μm while allowing the cathode emitter to be constructed on a massive electrode as heat sink in order to maintain a robust thermal management.

The proposed bandgap cascade under avalanche multiplication in a Schottky diode at 0.1 μm is really an ultra-thin and ultra-uniform film constructed epitaxially with two terminals; one Schottky electrode for thermal management as well as for the delivery of electrons, and one sink electrode under a sufficiently high applied field to deliver the carriers under avalanche multiplication with cascading bandgap energy. The pulse is also sufficiently short to reduce the effective duty cycle for a limited thermal load.

To construct the ultra-thin, uniform and precise wide bandgap semiconductor structure, we will use a silicon-based superlattice Si/C whose construction steps are disclosed as follows:
An effectively thin silicon wafer is used for template or substrate. Its surfaces are treated with HF acid to remove the surface oxides and other impurities while leaving an epi-surface thereof with dangling hydrogen atoms.
An effectively thin layer of silicon is deposited on the epi-surface preferably using either SiH₄ under CVD or silicon beam under ALD at 650° C. to obtain an epitaxial surface layer of high quality for superlattice construction.
A few, now best considered approximately 100 periods of Si/C, at one nm/period, are constructed on the epitaxial surface layer to provide an Si/C surface of a superlattice.
On the Si/C surface, an effective metal such as zirconium or tungsten is deposited to form a Zr-silicide electrode or W-silicide electrode, respectively, a few 10s of nm thick as a sink electrode 20.
The silicon substrate is now etched away with HCl. The etching process will be terminated chemically when it reaches the Si/C superlattice boundary because Si/C will resist the HCl etching to leave an Si/C superlattice 10.
The newly etched effectively smooth Si/C surface is coated with a relatively thick effective metal now best considered Nickel layer for a Schottky electrode 12 on which a layer of about 200 nm Pt or Au is coated for chemical stability. Edge 14 of the Schottky electrode is masked off from the metal deposition for edge-termination of the field as a leakage protection.
The Pt or Au coating is welded onto a massive copper electrode disc 16 having the same diameter as the wafer-sized Schottky device. The Cu-electrode is used also as a heat sink for thermal management.
An annular, ring-shaped contact 18 is placed on the sink electrode 20 to deliver the now preferred about 300 Volt positive pulse that initiates the avalanche multiplication over the preferably about 0.1 μm Si/C as a cathode emitter.

The other wide bandgap thin film materials for the bandgap cascade design, GaN, AlN, or both, have wider bandgap than SiC now considered preferred in the disclosure.

Variations, combinations and permutations of the above described method and device invention as will occur to those of ordinary skill are contemplated as within the scope of the following claims.

We claim:

1. In a method of a emitting from a cold cathode in an applied external field, the improvements comprising:
cascading bandgap energy during avalanche multiplication under reverse bias from a Schottky or p-n junction diode electrode to a sink electrode as a balance against a work function of the sink electrode for the sink electrode to function as the cold cathode emitter at a reduction of the applied external field.

2. The method according to claim 1, wherein the sink electrode comprises an effective metal on an Si/C surface of a superlattice.

3. The method according to claim 2, wherein the effective metal comprises zirconium or tungsten deposited to form a Zr-silicide or W-silicide sink electrode.

4. In a method of making a cold cathode, the improvements for bandgap cascade comprising:
constructing a few periods of Si/C at about one nm/period on a surface of effectively thin Si to form an Si/C surface of a superlattice;
depositing on the Si/C surface a first effective metal to form a metal-silicide sink electrode a few 10s of nm thick; and
forming a Schottky electrode on the superlattice opposite the sink electrode.

5. The method according to claim 4, wherein the few periods are approximately 100.

6. The method according to claim 4, wherein the first effective metal is zirconium or tungsten to form a Zr-silicide or W-silicide sink electrode.

7. The method according to claim 4, wherein forming the Schottky electrode comprises coating a nickel layer with Pt or Au.

8. The method according to claim 6, wherein forming the Schottky electrode comprises coating a nickel layer with Pt or Au.

9. The method according to claim 4, and further comprising providing an electrode and heat sink on the Schottky electrode.

10. The method according to claim 7, and further comprising providing an electrode and heat sink on the Schottky electrode.

11. The method according to claim 8, and further comprising providing an electrode and heat sink on the Schottky electrode.

12. The method according to claim 4, and further comprising providing a ring-shaped contact on the sink electrode.

13. The method according to claim 6, and further comprising providing a ring-shaped contact on the sink electrode.

14. The method according to claim 7, and further comprising providing a ring-shaped contact on the sink electrode.

15. The method according to claim 8, and further comprising providing a ring-shaped contact on the sink electrode.

16. The method according to claim 4, and further comprising:
treating surfaces of an effectively thin silicon wafer substrate with HF acid to remove surface oxides and other impurities while leaving at least an epitaxial surface thereof with dangling hydrogen atoms;
depositing on the epitaxial surface an effectively thin layer of Si either by SiH₄ under CVD or silicon beam under ALD at 650° C. to obtain an epitaxial surface layer thereon for superlattice construction;
etching away the silicon substrate to termination chemically when it reaches the Si/C superlattice boundary to form an effectively smooth Si/C surface thereon;
coating the effectively smooth Si/C surface with an effectively thick second metal effective to form a Schottky electrode surface on which a layer of about 200 nm Pt or Au is coated for chemical stability while masking off an edge of the Schottky electrode surface from the metal coatings for edge-termination of the field as a leakage protection;
welding the Pt or Au coating onto a Cu electrode disc having the same diameter as the Schottky electrode surface, the Cu electrode being sufficiently massive for a heat sink of thermal management; and
placing a ring-shaped contact on the Si/C surface for delivering a positive pulse that initiates avalanche multiplication over the Si/C as a cathode emitter.

17. The method according to claim 16, wherein the etching is with HCl.

18. A bandgap cascade cold cathode, comprising:
a few periods of Si/C at about one nm/period on a surface of a silicon superlattice;
a first effective metal a few 10s of nm thick on the surface as a metal-silicide sink electrode;
a second metal effective to form a Schottky electrode on an opposite surface of the silicon superlattice with a coating of about 200 nm Pt or Au thereon for chemical stability except at edges thereof for edge-termination of the field as a leakage protection;
a Cu electrode disc having the same diameter as the silicon superlattice welded to the Pt or Au coating for a heat sink of thermal management; and
a ring-shaped contact on the Si/C surface of the superlattice for delivering a positive pulse that initiates avalanche multiplication over the Si/C as a cathode emitter.

19. The bandgap cascade cold cathode according to claim 18, wherein the first effective metal is zirconium or tungsten to form a Zr-silicide or W-silicide sink electrode.

20. The bandgap cascade cold cathode according to claim 18, wherein the second effective metal is Ni.
